(19) United States
(12) Patent Application Publication
(10) Pub. No.: US 2025/0287713 A1
(43) Pub. Date: Sep. 11, 2025

(54) IMAGE SENSING DEVICE

(71) Applicant: SK hynix Inc., Icheon-si (KR)

(72) Inventor: Sung Wook CHO, Icheon-si (KR)

(21) Appl. No.: 18/820,100

(22) Filed: Aug. 29, 2024

(30) Foreign Application Priority Data
Mar. 8, 2024 (KR) 10-2024-0032910

(51) Int. Cl. H01L 27/146

(52) U.S. Cl. CPC H10F 39/807; H10F 39/182; H10F 39/8053; H10F 39/8063

(57) ABSTRACT

Image sensing devices are disclosed. In an embodiment, an image sensing device includes a pixel array including a plurality of unit pixels. Each of the unit pixels includes a plurality of subpixels. Each of the plurality of subpixels includes a first isolation layer disposed in an edge region of a corresponding subpixel, and a second isolation layer extending toward a center of the corresponding subpixel from the first isolation layer. The second isolation layer includes: a first disposed in a substrate; and a second layer disposed on the first layer and including a material with a lower refractive index and a lower light absorption rate than the first layer.

### CROSS-REFERENCE TO RELATED APPLICATIONS

This patent document claims the priority and benefits of Korean Patent Application No. 10-2024-0032910, filed on Mar. 8, 2024, which is incorporated by reference in its entirety as part of the disclosure of this patent document.

### TECHNICAL FIELD

Various embodiments of the disclosed technology relate to an image sensing device, and more particularly to an image sensing device capable of reducing optical loss.

### BACKGROUND

An image sensing device captures optical images by using the properties of photo-sensitive semiconductor materials that react to light. With the development of industries such as automobiles, medical treatment, computers, and communications, there is an increasing demand for high-performance image sensing devices in various fields such as smartphones, digital cameras, gaming devices, Internet of Things (IoT), robots, security cameras, and medical micro-cameras, etc.

The image sensing device may be broadly divided into charge coupled device (CCD) image sensing devices and complementary metal oxide semiconductor (CMOS) image sensing devices.

### SUMMARY

The disclosed technology can be implemented in some embodiments to provide an image sensing device capable of minimizing optical loss and of improving Gr/Gb, through a light incident region which includes a material having a low light absorptance and a low refractive index of an inner isolation layer.

In one embodiment, an image sensing device may include a pixel array including a plurality of unit pixels arranged. Each of the plurality of unit pixels includes a plurality of subpixels. Each of the plurality of subpixels includes a first isolation layer disposed in an edge region of a corresponding subpixel, and a second isolation layer extending toward a center of the corresponding subpixel from the first isolation layer. The second isolation layer includes: a first layer disposed in a substrate; and a second layer disposed on the first layer and including a material with a lower refractive index and lower light absorption rate than the first layer.

In some implementations, the second layer may include a material with a lower refractive index and lower light absorption rate than the first isolation layer.

In some implementations, the second isolation layer may include: a first inner isolation layer structured to protrude from one region of the first isolation layer toward the center of the corresponding subpixel; and a second inner isolation layer aligned with the first inner isolation layer and structured to protrude from another region of the first isolation layer toward the center of the subpixel.

In some implementations, the second inner isolation layer may be formed at a position spaced apart from the first inner isolation layer by a predetermined distance.

In some implementations, each of the plurality of subpixels may include a third isolation layer formed in a direction perpendicular to an area between the first inner isolation layer and the second inner isolation layer.

In some implementations, the third isolation layer may include a first region extending from the one region of the first isolation layer toward a section between the first inner isolation layer and the second inner isolation layer. In some implementations, the third isolation layer may include a second region extending from the other region of the first isolation layer toward the section between the first inner isolation layer and the second inner isolation layer.

In some implementations, the third isolation layer may include at least one of oxide, nitride, or oxynitride.

In some implementations, the second layer may include at least one of oxide, nitride, or oxynitride.

In some implementations, the first layer may include poly silicon.

In some implementations, each of the plurality of subpixels may further include: an insulating layer formed on the first isolation layer and the second isolation layer; a color filter formed on the insulating layer; and a microlens formed on the color filter. In some implementations, the third isolation layer is formed below the insulating layer.

In some implementations, the second isolation layer may include: a third inner isolation layer structured to protrude from a position of the first isolation layer perpendicular to the first inner isolation layer or the second inner isolation layer toward the center of the corresponding subpixel; and a fourth inner isolation layer aligned with the third inner isolation layer, and structured to protrude from a position of the first isolation layer facing the third inner isolation layer, toward the center of the subpixel. In some implementations, lengths of the third inner isolation layer and the fourth inner isolation layer that protrude from the first isolation layer toward the center of the corresponding subpixel may be shorter than a length of the first inner isolation layer or the second inner isolation layer that protrudes from the first isolation layer toward the center of the corresponding subpixel.

In some implementations, each of the plurality of subpixels includes a third isolation layer formed between the third inner isolation layer and the fourth inner isolation layer and between the first inner isolation layer and the second inner isolation layer.

In some implementations, each of the plurality of subpixels includes a third isolation layer formed between the third inner isolation layer and the fourth inner isolation layer. In some implementations, the third isolation layer includes a first region extending from the third inner isolation layer toward a section between the first inner isolation layer and the second inner isolation layer. In some implementations, the third isolation layer includes a second region extending from the fourth inner isolation layer toward the section between the first inner isolation layer and the second inner isolation layer.

In another embodiment, an image sensing device may include a pixel array including a plurality of unit pixels arranged. Each of the plurality of unit pixels includes a plurality of subpixels. Each of the plurality of subpixels includes a first isolation layer disposed in an edge region of a corresponding subpixel, and a second isolation layer extending toward a center of the corresponding subpixel from the first isolation layer. The second isolation layer includes: a first inner isolation layer structured to protrude from one region of the first isolation layer toward the center of the subpixel; a second inner isolation layer aligned with the first inner isolation layer and structured to protrude from another region of the first isolation layer toward the center of the subpixel; a third inner isolation layer structured to protrude from a position of the first isolation layer perpendicular to the first inner isolation layer or the second inner isolation layer toward the center of the subpixel; and a fourth inner isolation layer aligned with the third inner isolation layer, and structured to protrude from a position of the first isolation layer facing the third inner isolation layer toward the center of the subpixel. The first inner isolation layer, the second inner isolation layer, the third inner isolation layer, and the fourth inner isolation layer include: a first layer disposed in a substrate; and a second layer disposed on the first layer and including a material with a lower refractive index and lower light absorption rate than the first layer.

In some implementations, the second layer may include a material with a lower refractive index and lower light absorption rate than the first isolation layer.

In some implementations, the second layer may include at least one of oxide, nitride, or oxynitride.

In some implementations, the first layer may include poly silicon.

In some implementations, each of the plurality of subpixels may further include: an insulating layer formed on the first isolation layer and the second isolation layer; a color filter formed on the insulating layer; a microlens formed on the color filter; and a filter isolation layer formed on both sides of the color filter.

### BRIEF DESCRIPTION OF THE DRAWINGS

FIG. 1 is a block diagram of an image sensing device based on an embodiment of the disclosed technology.

FIG. 2 illustrates an example of a pixel array based on an embodiment.

FIGS. 3 to 8 illustrate examples of a subpixel of the pixel array based on an embodiment of the disclosed technology.

FIG. 9 is a cross sectional view of the subpixel of FIGS. 3 to 8 taken along line A-A′.

FIG. 10 is a cross sectional view of the subpixel of FIGS. 3 to 8 taken along line B-B′.

FIG. 11 is a view for describing a pixel array based on an embodiment of the disclosed technology.

FIG. 12 is a view for describing a subpixel of the pixel array based on an embodiment of the disclosed technology.

FIG. 13 is a cross sectional view of the subpixel of FIG. 12 taken along lines C-C′ and D-D′.

### DETAILED DESCRIPTION

Features, and certain advantages in connection with specific implementations of the disclosed technology disclosed in this patent document are described by example embodiments with reference to the accompanying drawings.

In the case of dual photodiode (2PD) type image sensing devices and quad photodiode (4PD) type image sensing devices, a portion of the incident light is absorbed by the deep trench isolation layer (DTI), resulting in optical loss.

In addition, a portion of the incident light is scattered by the DTI, penetrating the walls of adjacent pixels and causing crosstalk. As a result, depending on the direction of the DTI, the output signal difference (Gr/Gb) between a Gr pixel and a Gb pixel become either less than one or greater than one, leading to degradation. The disclosed technology can be implemented in some embodiments to address these issues. In some implementations, to address these issues, in the case of dual photodiode (2PD) type image sensing devices, the light incident region (e.g., an area where light enters) of the inner isolation layer includes a material with a lower refractive index and a lower light absorption rate than the refractive index and light absorption rate of the material of the outer isolation layer or the material of the region other than the light incident region in the inner isolation layer, so that unwanted light absorption or optical loss can be minimized, and an output signal difference (Gr/Gb) between a Gr pixel and a Gb pixel of a Bayer pattern can be improved. In addition, light absorption or optical loss is minimized by the light incident region of the inner isolation layer, which includes a material with a lower refractive index and light absorption rate, the difference between Gr and Gb is minimized, and thus, Gr/Gb can be made to have a value close to 1.

In the case of the quad photodiode (4PD) type image sensing device, the light incident region of the inner isolation layer includes a material with a lower refractive index and light absorption rate than the material of the outer isolation layer or the material of the region other than the light incident region in the inner isolation layer, minimizing light absorption or optical loss.

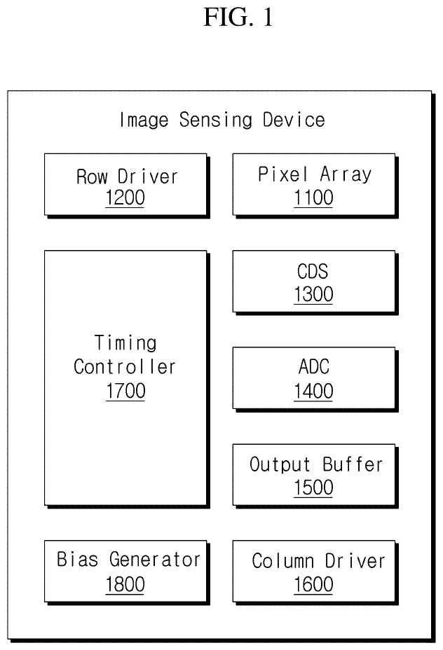

FIG. 1 is a block diagram of an image sensing device based on an embodiment of the disclosed technology.

Referring to FIG. 1, an image sensing device based on an embodiment may include a pixel array 1100, a row driver 1200, a correlated double sampler (CDS) 1300, and an analog-digital converter (ADC) 1400, an output buffer 1500, a column driver 1600, a timing controller 1700, and a bias generator 1800. Here, each of the components of the image sensing device is just an example, and at least some of the components may be added or omitted as needed.

The pixel array 1100 may include a plurality of pixels arranged in a plurality of rows and in a plurality of columns. In an embodiment, the plurality of pixels may be arranged in a two-dimensional pixel array including rows and columns. In another embodiment, a plurality of unit image pixels may be arranged in a three-dimensional pixel array. The plurality of pixels may convert an optical signal into an electrical signal on a pixel basis or a pixel group basis, and pixels within a pixel group may share at least a specific internal circuit. The pixel array 1100 may receive a drive signal including a row selection signal, a pixel reset signal, a transmission signal, etc., from the row driver 1200. The pixel of the pixel array 1100 may receive a row selection signal by the driving signal. The pixel of the pixel array 1100 may be activated, by the drive signal, to perform operations corresponding to the row selection signal, the pixel reset signal, and the transmission signal.

The row driver 1200 may activate the pixel array 1100 such that specific operations are performed on the pixels included in the row based on commands and control signals supplied by the timing controller 1700. In an embodiment, the row driver 1200 may select at least one pixel arranged in at least one row of the pixel array 1100.

The row driver 1200 may generate the row selection signal in order to select at least one row among the plurality of rows. The row driver 1200 may sequentially enable the pixel reset signal and the transmission signal for pixels corresponding to at least one selected row. Accordingly, an analog reference signal and analog image signal generated from each pixel of the selected row may be sequentially transmitted to the correlated double sampler 1300. Here, the reference signal may be an electrical signal provided to the correlated double sampler 1300 when a sensing node of the pixel (e.g., floating diffusion node) is reset. The image signal may be an electrical signal provided to the correlated double sampler 1300 when photocharges generated by the pixel is accumulated in the sensing node. The reference signal representing pixel-specific reset noise and the image signal representing the intensity of incident light may be collectively referred to as pixel signals.

A CMOS image sensor samples the pixel signal twice in order to remove the difference between two samples, so that correlated double sampling can be used such that unwanted offset values of the pixel such as fixed pattern noise are removed. As an example, the correlated double sampling compares pixel output voltages obtained before and after the photocharges generated by incident light are accumulated in the sensing node, thereby removing unwanted offset values and measuring the pixel output voltage based only on the incident light. In an embodiment, the correlated double sampler 1300 may sequentially sample and hold the reference signal and image signal provided to each of a plurality of column lines from the pixel array 1100. That is, the correlated double sampler 1300 may sample and hold the levels of the reference signal and image signal corresponding to each column of the pixel array 1100.

The correlated double sampler 1300 may transmit the reference signal and image signal of each column as a correlated double sampling signal to the ADC 1400 based on the control signal from the timing controller 1700.

The ADC 1400 may convert the correlated double sampling signal for each column output from the correlated double sampler 1300 into a digital signal and output it. In an embodiment, the ADC 1400 may be implemented as a ramp-compare type ADC. The ramp-compare type ADC may include a comparison circuit and a counter. The comparison circuit compares a ramp signal that rises or falls over time and an analog pixel signal. The counter performs a counting operation until the ramp signal matches the analog pixel signal. In an embodiment, the ADC 1400 may convert the correlated double sampling signal generated by the correlated double sampler 1300 for each of the columns into a digital signal and output it.

The ADC 1400 may include a plurality of column counters corresponding to the columns of the pixel array 1100, respectively. The columns of the pixel array 1100 may be connected to the column counters, respectively, and image data may be generated by converting the correlated double sampling signal corresponding to each column into a digital signal by using the column counters. Based on another embodiment, the ADC 1400 may include one global counter and may convert the correlated double sampling signal corresponding to each column into a digital signal by using a global code provided by the global counter.

The output buffer 1500 may temporarily hold and output image data in units of each column provided from the ADC 1400. The output buffer 1500 may temporarily store the image data output from the ADC 1400 based on the control signal of the timing controller 1700. The output buffer 1500 may operate as an interface that compensates for a difference in transmission (or processing) speed between the image sensing device and another device connected to the image sensing device.

The column driver 1600 may select a column of the output buffer 1500 based on the control signal of the timing controller 1700 and may control the image data temporarily stored in the selected column of the output buffer 1500 to be output sequentially. In an embodiment, the column driver 1600 may receive an address signal from the timing controller 1700, and the column driver 1600 may generate a column selection signal based on the address signal and may select the column of the output buffer 1500, thereby controlling the image data to be output from the selected column of the output buffer 1500 to the outside.

The timing controller 1700 may control at least one of the row driver 1200, the correlated double sampler 1300, the ADC 1400, the output buffer 1500, the column driver 1600, or the bias generator 1800.

The timing controller 1700 may provide a clock signal required for the operation of each component of the image sensing device, the control signal for timing control, the address signal for selecting rows or columns, and a signal for controlling the level of a bias voltage applied to the pixel array 1100, etc., to at least one of the row driver 1200, the correlated double sampler 1300, the ADC 1400, the output buffer 1500, the column driver 1600, or the bias generator 1800. In an embodiment, the timing controller 1700 may include a logic control circuit, a phase lock loop (PLL) circuit, a timing control circuit, and a communication interface circuit, etc.

The bias generator 1800 may generate a bias voltage to suppress dark current which is generated in the pixel of the pixel array 1100 and may supply the bias voltage to the pixel array 1100.

The bias voltage may be determined during a wafer probe test of the image sensing device and may be stored in one-time programmable memory (OTP). For example, the bias voltage has a value capable of minimizing unnecessary power consumption without degrading the performance of the image sensing device and of maximizing an effect of suppressing the dark current. The value of the bias voltage can be experimentally determined.

The bias generator 1800 may generate a voltage corresponding to the bias voltage stored in the OTP memory. In an embodiment, the OTP memory may be included in the image sensing device, and in particular may be included in the bias generator 1800.

In an embodiment, the bias voltage may include a plurality of values.

For example, the plurality of values may correspond to a plurality of operation modes of the image sensing device, respectively. The dark currents generated at low and high illuminances may be different from each other, and the bias voltage supplied by the bias generator 1800 in order to effectively suppress the dark current in each environment may vary depending on the mode.

Alternatively, the plurality of values may correspond to a plurality of regions of the pixel array 1100, respectively. The dark currents generated based on the position of the pixel on the pixel array 1100 may be different from each other, and the bias voltage supplied by the bias generator 1800 in order to effectively suppress the dark current regardless of the position of the pixel may vary depending on the region.

The bias voltage may be a negative voltage with a negative sign. However, the scope of the disclosed technology is not limited thereto.

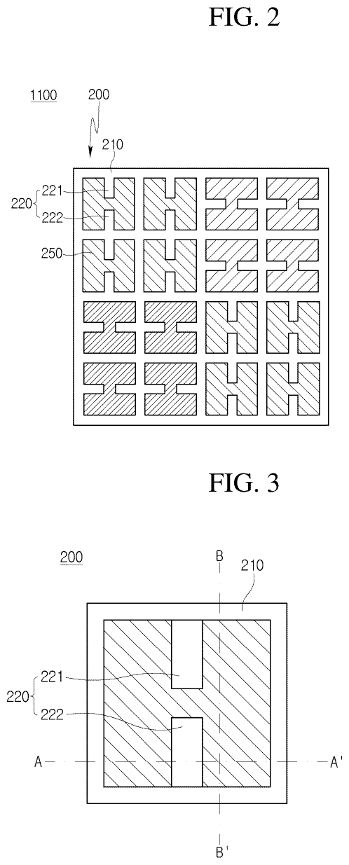

FIG. 2 illustrates an example of a pixel array based on an embodiment. FIGS. 3 to 8 illustrate examples of a subpixel of the pixel array based on the first embodiment. FIG. 9 is a cross sectional view of the subpixel of FIGS. 3 to 8 taken along line A-A′. FIG. 10 is a cross sectional view of the subpixel of FIGS. 3 to 8 taken along line B-B′.

Referring to FIG. 2, the image sensing device based on an embodiment may be a dual photodiode (2PD) type image sensing device.

As an example, the pixel array 1100 may include a plurality of unit pixels. In some implementations, each unit pixel may include four subpixels 200 including the same color filter. Two photodiodes may be formed below each color filter.

A first isolation layer 210 may be formed in the edge region of the subpixels 200 (boundary area between the subpixels 200). In some implementations, the first isolation layer 210 is an outer isolation layer and may be formed in a vertically deep trench to prevent crosstalk between adjacent subpixels 200. In some implementations, the first isolation layer 210 may be formed through a deep trench isolation layer (DTI) process.

The first isolation layer 210 may include at least one of silicon oxynitride (SiON) film, silicon nitride (SiN) film, or poly silicon (poly Si).

A second isolation layer 220 may be surrounded by the first isolation layer 210. The second isolation layer 220 may extend toward the center of the subpixel 200 from the first isolation layer 210.

The second isolation layer 220 is an inner isolation layer, and may be formed in a vertically deep trench to prevent crosstalk between adjacent photodiodes, and may be formed through a deep trench isolation (DTI) process.

Referring to FIGS. 3 and 9, the second isolation layer 220 may include, for example, a first inner isolation layer 221 and a second inner isolation layer 222.

The first inner isolation layer 221 may be formed to protrude from one region of the first isolation layer 210 toward the center of the subpixel 200.

In some implementations, the second inner isolation layer 222 may be aligned with the first inner isolation layer 221. For example, the second inner isolation layer 222 may be formed on the same straight line with the first inner isolation layer 221. In some implementations, the second inner isolation layer 222 may be formed to protrude from the other region of the first isolation layer 210 (region in the opposite direction to where the first inner isolation layer 221 is formed) toward the center of the subpixel 200.

The second isolation layer 220, that is, the first inner isolation layer 221 and the second inner isolation layer 222, may include, for example, a first layer 11 and a second layer 12.

For example, the first layer 11 may be formed in a substrate 290 and may include a material with a higher refractive index than silicon (Si).

The first layer 11 may include, for example, poly silicon (poly Si).

The first layer 11 may include, for example, at least one of silicon oxynitride (SiON) film, silicon oxide (SiO) film, silicon nitride (SiN), or poly silicon (poly Si).

The second layer 12 may be, for example, formed on the first layer 11 and may include a material with a lower refractive index and lower light absorption rate than polysilicon (Poly Si).

The second layer 12 may include, for example, at least one of oxide, nitride, or oxynitride.

The second layer 12 of the second isolation layer 220, on which light is incident through a microlens 270, includes a material with a lower refractive index and light absorption rate than the first isolation layer 210 or the first layer 11, so that light absorption or optical loss can be minimized, and an output signal difference (Gr/Gb) between a Gr pixel and a Gb pixel of a Bayer pattern can be improved. The light absorption or optical loss is minimized through the second layer 12 of the second isolation layer 220 including the material with a lower refractive index and light absorption rate than poly silicon (Poly Si), the difference between Gr and Gb is minimized, and thus, Gr/Gb can be made to have a value close to 1.

The second inner isolation layer 222 may be, for example, formed at a position spaced apart from the first inner isolation layer 221 by a predetermined distance or space. The predetermined distance (or space) may have various values depending on settings.

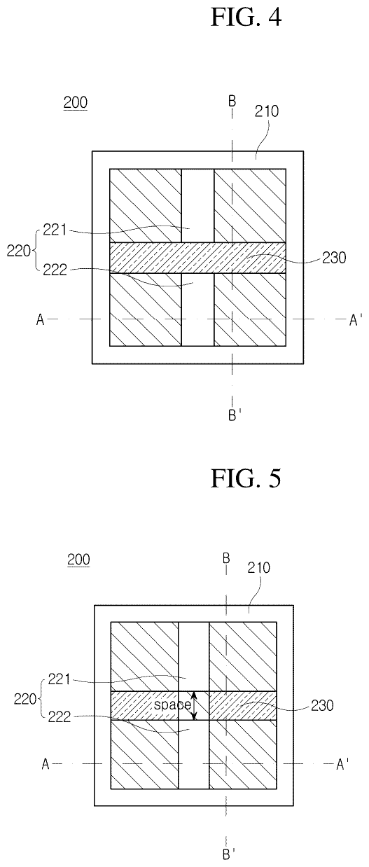

Referring to FIG. 4, a third isolation layer 230 may be, for example, formed in a direction perpendicular to an area between the first inner isolation layer 221 and the second inner isolation layer 222.

One side of the third isolation layer 230 may be formed to contact one side of the first isolation layer 210, and the other side of the third isolation layer 230 may be formed to contact the other side of the first isolation layer 210.

Referring to FIG. 5, the third isolation layer 230 may be, for example, formed to extend to the region between the first inner isolation layer 221 and the second inner isolation layer 222.

The third isolation layer 230 may include, for example, a material with a lower refractive index than silicon (Si).

The third isolation layer 230 may include, for example, oxide.

The third isolation layer 230 may include, for example, at least one of oxide, nitride, or oxynitride.

The third isolation layer 230 may be, for example, formed to contact an oxide layer (not shown) of the second isolation layer 220.

Referring to FIG. 5, the third isolation layer 230 may be, for example, formed other than in the region between the first inner isolation layer 221 and the second inner isolation layer 222 in a direction perpendicular to an area between the first inner isolation layer 221 and the second inner isolation layer 222. That is, one region of the third isolation layer 230 may be formed to extend from one region of the first isolation layer 210 to a section between the first inner isolation layer 221 and the second inner isolation layer 222. The other region of the third isolation layer 230 may be formed to extend from the other region of the first isolation layer 210 to the section between the first inner isolation layer 221 and the second inner isolation layer 222.

The third isolation layer 230 may be, for example, formed to be spaced apart from an oxide layer (not shown) of the second isolation layer 220.

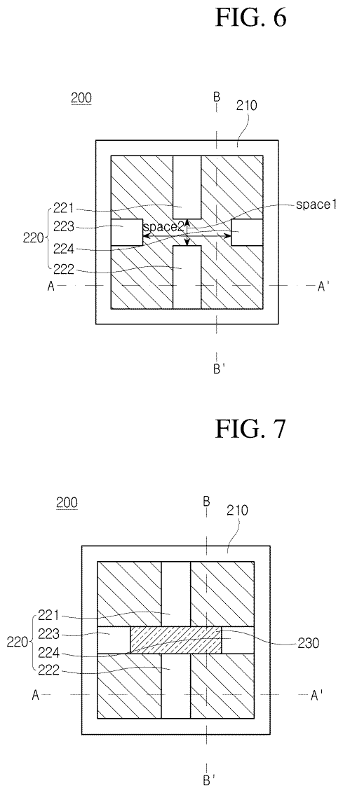

Referring to FIG. 6, the second isolation layer may further include, for example, a third inner isolation layer 223 and a fourth inner isolation layer 224.

The third inner isolation layer 223 may be, for example, formed to protrude from the first isolation layer 210 at a position perpendicular to the first inner isolation layer 221 or the second inner isolation layer 222 toward the center of the subpixel 200.

In some implementations, the fourth inner isolation layer 224 may be aligned with the third inner isolation layer 223. For example, the fourth inner isolation layer 224 may be formed on the same straight line with the third inner isolation layer 223. In some implementations, the fourth inner isolation layer 224 may be formed to protrude from the first isolation layer 210 at a position facing the third inner isolation layer 223 toward the center of the subpixel 200.

As an example, the protruding length from the first isolation layer 210 of the third inner isolation layer 223 and the fourth inner isolation layer 224 toward the center of the subpixel 200 may be less than the protruding length from the first isolation layer 210 of the first inner isolation layer 221 or the second inner isolation layer 222 toward the center of the subpixel 200. As an example, the protruding length from the first isolation layer 210 of the third inner isolation layer 223 and the fourth inner isolation layer 224 toward the center of the subpixel 200 may be the same as the protruding length from the first isolation layer 210 of the first inner isolation layer 221 or the second inner isolation layer 222 toward the center of the subpixel 200. In some embodiments, the term “protruding length” above may indicate a length of the first inner isolation layer 221 or the second inner isolation layer 222 that protrudes from the first isolation layer 210 toward the center of the subpixel 200.

As an example, a gap (space2) between the third inner isolation layer 223 and the fourth inner isolation layer 224 may be greater than a gap (space1) between the first inner isolation layer 221 and the second inner isolation layer 222. As an example, the gap (space2) between the third inner isolation layer 223 and the fourth inner isolation layer 224 may be the same as the gap (space1) between the first inner isolation layer 221 and the second inner isolation layer 222.

Referring to FIGS. 6 and 9, the third inner isolation layer 223 and the fourth inner isolation layer 224 may include the first layer 11 and the second layer 12.

For example, the first layer 11 may be formed on the substrate 290 and may include a material with a higher refractive index than silicon (Si).

The first layer 11 may include, for example, poly silicon (poly Si).

The first layer 11 may include, for example, at least one of silicon oxynitride (SiON) film, silicon oxide (SiO) film, silicon nitride (SiN), or poly silicon (poly Si).

The second layer 12 may be, for example, formed on the first layer 11 and may include a material with a lower refractive index and lower light absorption rate than polysilicon (Poly Si).

The second layer 12 may include, for example, at least one of oxide, nitride, or oxynitride.

Referring to FIG. 7, the third isolation layer 230 may be, for example, formed between the third inner isolation layer 223 and the fourth inner isolation layer 224 and between the first inner isolation layer 221 and the second inner isolation layer 222.

The third isolation layer 230 may be, for example, formed to contact an oxide layer (not shown) of the second isolation layer 220.

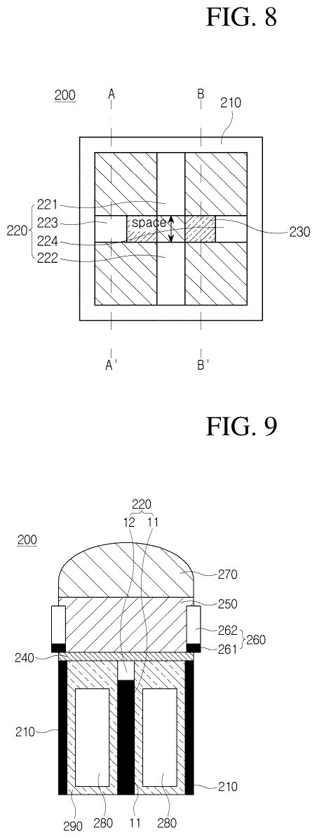

Referring to FIG. 8, the third isolation layer 230 may be, for example, formed between the third inner isolation layer 223 and the fourth inner isolation layer 224 other than in the region between the first inner isolation layer 221 and the second inner isolation layer 222. That is, one region of the third isolation layer 230 may be formed to extend from the third inner isolation layer 223 to a section between the first inner isolation layer 221 and the second inner isolation layer 222. The other region of the third isolation layer 230 may be formed to extend from the fourth inner isolation layer 224 to the section between the first inner isolation layer 221 and the second inner isolation layer 222.

The third isolation layer 230 may be, for example, formed to be spaced apart from an oxide layer (not shown) of the second isolation layer 220.

Referring to FIGS. 9 and 10, the subpixel 200 may include the first isolation layer 210, the second isolation layer 220, the third isolation layer 230, an insulating layer 240, and a color filter 250, a filter isolation layer 260, the microlens 270, a photodiode 280, and the substrate 290.

The first isolation layer 210 may be formed between adjacent subpixels 200.

The second isolation layer 220 may include the first inner isolation layer 221 and second inner isolation layer 222, or may include the first inner isolation layer 221, the second inner isolation layer 222, the third inner isolation layer 223, and the fourth inner isolation layer 224.

An oxide layer (not shown) may be, for example, formed on sidewalls of the first isolation layer 210 and the second isolation layer 220.

The insulating layer 240 may be formed on the first isolation layer 210 and the second isolation layer 220, and may include at least one of oxide, nitride, or oxynitride.

The third isolation layer 230 may be formed below the insulating layer 240.

The color filter 250 may be formed on the insulating layer 240, and may filter visible light from the light incident through the microlens 270 and transmit the visible light. The color filter 250 may include at least any one of a blue color filter that allows only blue light in visible light to pass through, a green color filter that allows only green light in visible light to pass through, and a red color filter that allows only red light in visible light to pass through. However, based on an embodiment, a white color filter that allows light of all colors to pass therethrough may be used, or the color filter may be omitted.

The filter isolation layer 260 may be, for example, a metal grid including a metal material (e.g., titanium nitride (TiN) film, tungsten (W)), or an air grid including an air region.

The microlens 270 is formed on the color filter 250 and serves to concentrate light incident from the outside.

The photodiode 280 may be formed in the inner region of the substrate 290 and in a region lower the insulating layer 240, and may be formed by vertically stacking an N-type impurity region and a P-type impurity region. The N-type impurity region and the P-type impurity region may be formed through an ion implantation process.

The substrate 290 may include a single crystalline silicon (Si) material.

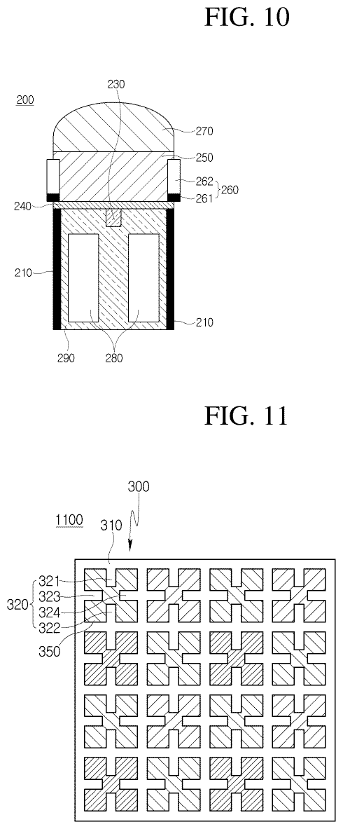

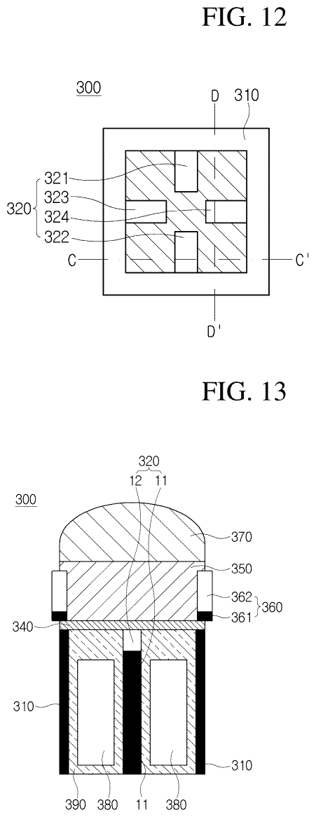

FIG. 11 is a view for describing a pixel array based on an embodiment. FIG. 12 is a view for describing a subpixel of the pixel array based on an embodiment. FIG. 13 is a cross sectional view of the subpixel of FIG. 12 taken along lines C-C′ and D-D′.

Referring to FIG. 11, an image sensing device based on an embodiment may be a quad photodiode (4PD) type image sensing device.

As an example, the pixel array 1100 may include a plurality of unit pixels. Each unit pixel may include four subpixels including the same color filter. Four photodiodes may be formed below each color filter.

A first isolation layer 310 may be formed in the edge region of the subpixels 300 (boundary area between subpixels 300). The first isolation layer 310 may be formed in a vertically deep trench to prevent crosstalk between adjacent subpixels 300, and may be formed through a deep trench isolation (DTI) process.

The first isolation layer 310 may include at least one of silicon oxynitride (SiON) film, silicon nitride (SiN) film, or poly silicon (poly Si).

A second isolation layer 320 may be surrounded by the first isolation layer 310. The second isolation layer 320 may extend toward the center of the subpixel 300 from the first isolation layer 310.

The second isolation layer 320 may be formed in a vertically deep trench to prevent crosstalk between adjacent photodiodes, and may be formed through a deep trench isolation (DTI) process.

Referring to FIGS. 12 and 13, the second isolation layer 320 may include, for example, a first inner isolation layer 321, a second inner isolation layer 322, a third inner isolation layer 323, a fourth inner isolation layer 324.

The first inner isolation layer 321 may be formed to protrude from one region of the first isolation layer 310 toward the center of the subpixel 300.

The second inner isolation layer 322 may be formed on the same straight line with the first inner isolation layer 321, and may be formed to protrude from the other region of the first isolation layer 310 (region in the opposite direction to which the first inner isolation layer 321 is formed) toward the center of the subpixel 300.

The third inner isolation layer 323 may be formed to protrude from the first isolation layer 310 at a position perpendicular to the first inner isolation layer 321 or the second inner isolation layer 322 toward the center of the subpixel 300.

The fourth inner isolation layer 324 may be formed on the same straight line with the third inner isolation layer 323, and may be formed to protrude from the first isolation layer 310 at a position facing the third inner isolation layer 323 toward the center of the subpixel 300.

The first inner isolation layer 321, the second inner isolation layer 322, the third

inner isolation layer 323, and the fourth inner isolation layer 324 may include, for example, a first layer 11 and a second layer 12.

For example, the first layer 11 may be formed in a substrate 390 and may include a material with a higher refractive index than silicon (Si).

The first layer 11 may include, for example, poly silicon (poly Si).

The first layer 11 may include, for example, at least one of silicon oxynitride (SiON) film, silicon oxide (SiO) film, silicon nitride (SiN), or poly silicon (poly Si).

The second layer 12 may be, for example, formed on the first layer 11 and may include a material with a lower refractive index and lower light absorption rate than polysilicon (Poly Si).

The second layer 12 may include, for example, at least one of oxide, nitride, or oxynitride.

The second layer 12 of the second isolation layer 320, on which light is incident through a microlens 370, includes a material with a lower refractive index and light absorption rate than the first isolation layer 310 or the first layer 11, so that light absorption or optical loss can be minimized.

The second inner isolation layer 322 may be, for example, formed at a position spaced apart from the first inner isolation layer 321 by a predetermined distance (or space). The fourth inner isolation layer 324 may be, for example, formed at a position spaced apart from the third inner isolation layer 323 by a predetermined distance (or space). The predetermined distance (or space) may have various values depending on settings.

Referring to FIG. 13, the subpixel 300 may include the first isolation layer 310, the second isolation layer 320, an insulating layer 340, and a color filter 350, a filter isolation layer 360, the microlens 370, a photodiode 280, and the substrate 390.

The first isolation layer 310 may be formed between adjacent subpixels 300.

The second isolation layer 320 may include the first inner isolation layer 321, the second inner isolation layer 322, the third inner isolation layer 323, and the fourth inner isolation layer 324.

The insulating layer 340 may be formed on the first isolation layer 310 and the second isolation layer 320, and may include at least one of oxide, nitride, or oxynitride.

The color filter 350 may be formed on the insulating layer 340, and may filter visible light from the light incident through the microlens 370 and transmit the visible light. The color filter 350 may include at least any one of a blue color filter that allows only blue light in visible light to pass through, a green color filter that allows only green light in visible light to pass through, and a red color filter that allows only red light in visible light to pass through. However, based on an embodiment, a white color filter that allows light of all colors to pass therethrough may be used, or the color filter may be omitted.

The filter isolation layer 360 may be, for example, a metal grid including a metal material (e.g., titanium nitride (TiN) film, tungsten (W)), or an air grid including an air region.

The microlens 370 is formed on the color filter 350 and serves to concentrate light incident from the outside.

The photodiode 380 may be formed in the inner region of the substrate 390 and in a region lower the insulating layer 340, and may be formed by vertically stacking an N-type impurity region and a P-type impurity region. The N-type impurity region and the P-type impurity region may be formed through an ion implantation process.

The substrate 390 may include a single crystalline silicon (Si) material.

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples of the disclosed technology are described and other implementations, enhancements and variations can be made based on what is described and illustrated in this patent document.

What is claimed is:

1. An image sensing device comprising:
a pixel array including a plurality of unit pixels arranged,
wherein each of the plurality of unit pixels includes a plurality of subpixels,
wherein each of the plurality of subpixels includes:
a first isolation layer disposed in an edge region of a corresponding subpixel; and
a second isolation layer extending toward a center of the corresponding subpixel from the first isolation layer,
wherein the second isolation layer includes:
a first layer disposed in a substrate; and
a second layer disposed on the first layer and including a material with a lower refractive index and lower light absorption rate than the first layer.

2. The image sensing device of claim 1, wherein the second layer includes a material with a lower refractive index and lower light absorption rate than the first isolation layer.

3. The image sensing device of claim 1, wherein the second isolation layer includes:
a first inner isolation layer structured to protrude from one region of the first isolation layer toward the center of the corresponding subpixel; and
a second inner isolation layer aligned with the first inner isolation layer and structured to protrude from another region of the first isolation layer toward the center of the subpixel.

4. The image sensing device of claim 3, wherein the second inner isolation layer is formed at a position spaced apart from the first inner isolation layer by a predetermined distance.

5. The image sensing device of claim 3, wherein each of the plurality of subpixels includes a third isolation layer formed in a direction perpendicular to an area between the first inner isolation layer and the second inner isolation layer.

6. The image sensing device of claim 5, wherein the third isolation layer includes:
a first region extending from the one region of the first isolation layer toward a section between the first inner isolation layer and the second inner isolation layer; and
a second region extending from the other region of the first isolation layer toward the section between the first inner isolation layer and the second inner isolation layer.

7. The image sensing device of claim 5, wherein the third isolation layer includes at least one of oxide, nitride, or oxynitride.

8. The image sensing device of claim 1, wherein the second layer includes at least one of oxide, nitride, or oxynitride.

9. The image sensing device of claim 1, wherein the first layer includes poly silicon.

10. The image sensing device of claim 5, wherein each of the plurality of subpixels further includes:
an insulating layer formed on the first isolation layer and the second isolation layer;
a color filter formed on the insulating layer; and
a microlens formed on the color filter,
wherein the third isolation layer is formed below the insulating layer.

11. The image sensing device of claim 3,
wherein the second isolation layer includes:
a third inner isolation layer structured to protrude from a position of the first isolation layer perpendicular to the first inner isolation layer or the second inner isolation layer toward the center of the corresponding subpixel; and
a fourth inner isolation layer aligned with the third inner isolation layer, and structured to protrude from a position of the first isolation layer facing the third inner isolation layer, toward the center of the subpixel, and
wherein lengths of the third inner isolation layer and the fourth inner isolation layer that protrude from the first isolation layer toward the center of the corresponding subpixel are shorter than a length of the first inner isolation layer or the second inner isolation layer that protrudes from the first isolation layer toward the center of the corresponding subpixel.

12. The image sensing device of claim 11, wherein each of the plurality of subpixels includes a third isolation layer formed between the third inner isolation layer and the fourth inner isolation layer and between the first inner isolation layer and the second inner isolation layer.

13. The image sensing device of claim 11,
wherein each of the plurality of subpixels includes a third isolation layer is formed between the third inner isolation layer and the fourth inner isolation layer, wherein the third isolation layer includes:
a first region extending from the third inner isolation layer toward a section between the first inner isolation layer and the second inner isolation layer, and
a second region extending from the fourth inner isolation layer toward the section between the first inner isolation layer and the second inner isolation layer.

14. An image sensing device comprising:
a pixel array including a plurality of unit pixels arranged,
wherein each of the plurality of unit pixels includes a plurality of subpixels,
wherein each of the plurality of subpixels includes:
a first isolation layer disposed in an edge region of a corresponding subpixel; and
a second isolation layer extending toward a center of the corresponding subpixel from the first isolation layer,
wherein the second isolation layer includes:
a first inner isolation layer structured to protrude from one region of the first isolation layer toward the center of the subpixel;
a second inner isolation layer aligned with the first inner isolation layer and structured to protrude from anther region of the first isolation layer toward the center of the subpixel;
a third inner isolation layer structured to protrude from a position of the first isolation layer perpendicular to the first inner isolation layer or the second inner isolation layer toward the center of the subpixel; and
a fourth inner isolation layer aligned with the third inner isolation layer, and structured to protrude from a position of the first isolation layer facing the third inner isolation layer toward the center of the subpixel, and
wherein the first inner isolation layer, the second inner isolation layer, the third inner isolation layer, and the fourth inner isolation layer include:
a first layer disposed in a substrate; and
a second layer disposed on the first layer and including a material with a lower refractive index and lower light absorption rate than the first layer.

15. The image sensing device of claim 14, wherein the second layer includes a material with a lower refractive index and lower light absorption rate than the first isolation layer.

16. The image sensing device of claim 14, wherein the second layer includes at least one of oxide, nitride, or oxynitride.

17. The image sensing device of claim 14, wherein the first layer includes poly silicon.

18. The image sensing device of claim 14, wherein each of the plurality of subpixels further includes:
an insulating layer formed on the first isolation layer and the second isolation layer;
a color filter formed on the insulating layer;
a microlens formed on the color filter; and
a filter isolation layer formed on both sides of the color filter.
